(19) United States
(12) Patent Application Publication
(10) Pub. No.: US 2006/0172555 A1
(43) Pub. Date: Aug. 3, 2006

(54) Method to make silicon nanoparticle from silicon rich-oxide by DC reactive sputtering for electroluminescence application

(75) Inventors: Wei Gao, Vancouver, WA (US); Tingkai Li, Vancouver, WA (US); Yoshi Ono, Camas, WA (US); Sheng Teng Hsu, Camas, WA (US)

Correspondence Address: ROBERT D. VARITZ, 4915 S.E. 33RD PLACE, PORTLAND, OR, 97202, US

(73) Assignee: Sharp Laboratories of America, Inc.

(21) Appl. No.: 11/049,594

(22) Filed: Feb. 1, 2005

(51) Int. Cl. H01L 21/31

(52) U.S. Cl. 438/787

(57) ABSTRACT

A method of forming a silicon-rich silicon oxide layer having nanometer sized silicon particles therein includes preparing a substrate; preparing a target; placing the substrate and the target in a sputtering chamber; setting the sputtering chamber parameters; depositing material from the target onto the substrate to form a silicon-rich silicon oxide layer; and annealing the substrate to form nanometer sized silicon particles therein.

### FIELD OF THE INVENTION

This invention relates to silicon based electroluminescence devices, and specifically to formation of a silicon-rich silicon oxide EL device.

### BACKGROUND OF THE INVENTION

Since Castagna et al., High efficiency light emission devices in silicon, Mat. Res. Soc. Symp. Proc., Vol. 770, 12.1.1-12.1.12, (2003), demonstrated the working of an electroluminescence (EL) device by using silicon-rich silicon oxide (SRSO) as the light emitting material, silicon-based EL device have increasingly been incorporated into silicon-based integrated circuits. For economic reasons, research into silicon-based EL devices has become an important matter. The basic mechanism of silicon light emitting material requires that silicon be reduced to nanometer size particles and embedded in a suitable substrate. Because of the quantum confinement effect, and with rare-earth doping, the material containing silicon nanoparticles (NPs) can emit light of various wavelengths. The biggest technical challenge is to generate high density silicon NPs dispersed in a silicon dioxide matrix.

Two techniques for distributing high density silicon NPs in a silicon dioxide matrix have been reported. One is to deposit an SRSO film and anneal the film at a high temperature to allow excess silicon to diffuse and form NPs. The other technique is to fabricate a Si/SiO multilayer structure, sometimes called superlattice (SL), and then anneal the SL at high temperature to form silicon NPs. The deposition methods for SRSO include CVD and silicon ion implantation into SiO₂ and the rare-earth doping is normally performed by ion implantation. For a Si/SiO₂ SL structure, CVD is also commonly used with varying gas composition. RF sputtering to deposit a silicon film and oxygen plasma to oxidize part of the film has been attempted, without successful results. For these deposition methods, one or more ion implantation is normally needed, which raises the cost and limits the flexibility of commercialization. Interface dopant engineering is not possible for this method.

Prior art methods employ CVD to generate either SRSO or SL film structures, followed by ion implantation of silicon or rare-earth dopants. A single-step implantation cannot distribute the dopant uniformly across the active thickness of the film, thus, multiple implantation steps are used, however, such implantation still may not achieve high light emitting efficiency and is not cost effective. At the same time, the interface engineering for dopants is not possible. RF sputtering has been used for generating SL structures by depositing a silicon film and plasma oxidizing part of the film, but the process is complex, and is likely not commercially feasible.

### SUMMARY OF THE INVENTION

A method of forming a silicon-rich silicon oxide layer having nanometer sized silicon particles therein includes preparing a substrate; preparing a target; placing the substrate and the target in a sputtering chamber; setting the sputtering chamber parameters; depositing material from the target onto the substrate to form a silicon-rich silicon oxide layer; and annealing the substrate to form nanometer sized silicon particles therein.

This summary of the invention is provided to enable quick comprehension of the nature of the invention. A more thorough understanding of the invention may be obtained by reference to the following detailed description of the preferred embodiment of the invention in connection with the drawings.

### BRIEF DESCRIPTION OF THE DRAWINGS

FIG. 1 is a block diagram of the method of the invention.

FIG. 2 depicts a thickness calibration for Si and SiO₂ deposition.

FIG. 3 is a plot of the atomic O/Si ratio changes when the power is varied from 150 W to 300 W.

FIG. 4 depicts the ellipsometry measurements on three samples.

FIG. 5 depicts changes in crystal size with changes in annealing temperature.

### DETAILED DESCRIPTION OF THE PREFERRED EMBODIMENTS

In this invention, a reactive DC sputtering method is used to deposit silicon-rich silicon oxide (SRSO) at a low deposition temperature, followed by thermal annealing to generate silicon nanoparticles in SiO₂. Rare earth doping may be performed by co-sputtering, or by using a dopant-embedded target, which eliminates the ion implantation process, which reduces fabrication expense and time, and which provides better control of the doping density and doping profile in the film. Because only one silicon target is used, the fabrication process may easily be optimized. This invention provides a flexible and easy method to make silicon NPs wherein rare-earth doping and location control are easily achieved.

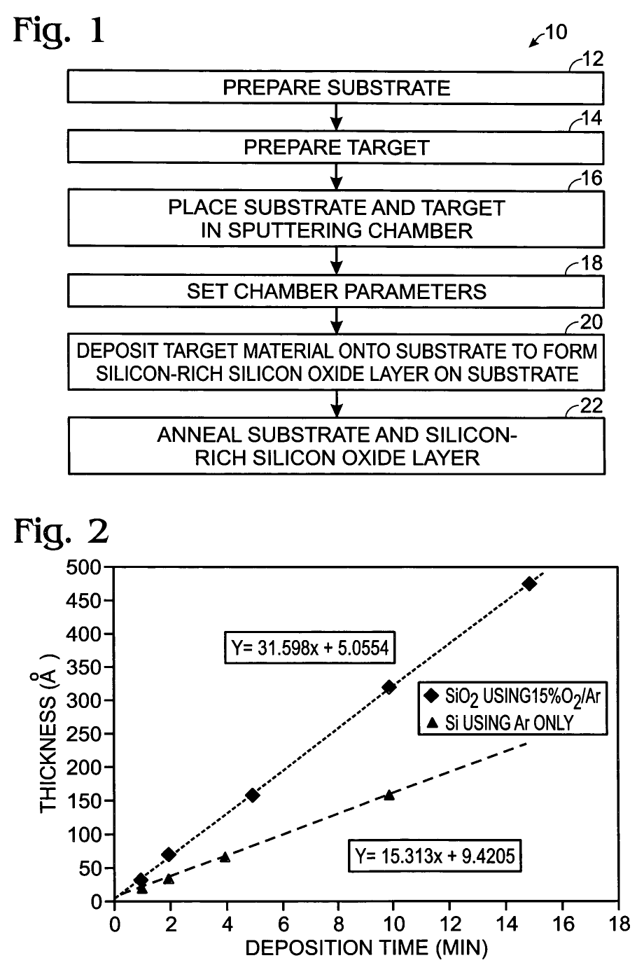

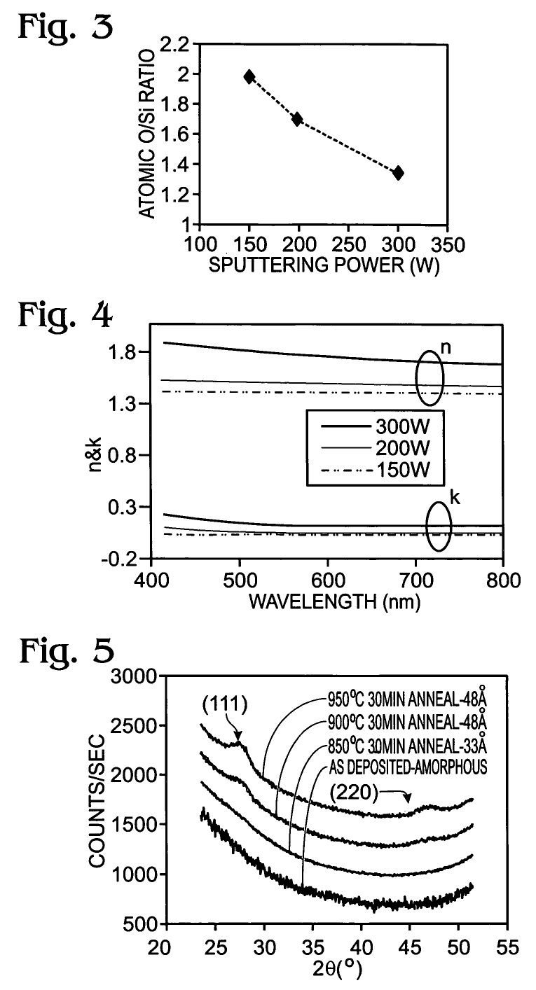

Referring now to FIG. 1, the method of the invention is depicted generally at 10. The invention includes preparation of a substrate 12, which may be a bulk silicon substrate, or a substrate having integrated circuit devices formed thereon, which may have other elements of an integrated circuit fabricated thereon. A sputtering target is also prepared 14, which target may be pure silicon, or amorphous silicon doped with any desired dopants. DC sputtering deposition is performed in Edwards 360 system using a 4-inch silicon target, which is placed in the chamber, along with substrate 12. Deposition chamber parameters are set 18. Deposition 20 may be performed at room temperature for an amorphous silicon film and at about 250° C. for an amorphous silicon and a silicon oxide film. Deposition pressure is maintained at between about 7 mtorr to 8 mtorr. The oxygen concentration in the gas phase is changed by varying the ratio of oxygen flow to Ar flow, from 30% O₂ to 0% O₂, resulting in film composition changing from SiO₂ to pure silicon, respectively, as shown in FIG. 2, which depicts the thickness calibration for silicon and SiO₂. As shown in FIG. 2, the thickness calibration for silicon and SiO₂ deposition by using pure argon and a mixture of 15% O₂/85% Ar, respectively. The y-intercept begins with a thickness of a few Å because of the initial cleaning procedure that takes place prior to shutter opening. An SRSO film having a refractive index value ranging from about 1.46 to 1.8 is deemed best suited for use in a silicon EL device. To achieve the desired refractive index, composition control is achieved by using a fixed 15% O₂/85% Ar in the form of a premixed gas and varying the sputtering power. Table 1 depicts the results of three samples, which were deposited at 250° C. by applying sputtering power from 150 W to 300 W. The atomic composition of the films were measured by the Rutherford Backscattering (RBS) method. FIG. 3 depicts compositional properties of the SRSO films deposited at different sputtering power by using 15% O₂/85% Ar premixed gas in a plot of the atomic oxygen/silicon ratio changes when the power is varied from 150 W to 300 W. At 150 W, the x value is 2.0, representing a stoichiometric silicon dioxide; when the power is increased, the film becomes silicon rich. At 200 W, the refractive index, at 633 nm, is around 1.52 and x value is 1.7; and at 300 W, the refractive index, at 633 nm, is 1.78, the x value in SiOₓ film is lowered to 1.34, which is equivalent to 50% silicon rich. FIG. 4 depicts optical property changes for different silicon rich silicon oxides deposited at different power in terms of ellipsometry measurements on these three samples, and the optical properties of these films confirmed RBS results.

TABLE 1

| | | | |
|---|---|---|---|
| Wafer ID | 1335 | 1339 | 1336 |
| Power (W) | 150 | 200 | 300 |
| Si atom %-age | 32 | 36.65 | 40.9 |
| O atom %-age | 64 | 61.5 | 55 |
| O/SI ratio (X value) | 2.0 | 1.70 | 1.34 |

From silicon rich silicon oxide deposited by this sputtering method, the silicon nanoparticles may be generated in the silicon dioxide matrix by thermal annealing, 22, at a temperature of between about 850° C. to 1,200° C., FIG. 1. FIG. 5 depicts the crystal size change after annealing at different temperature. From amorphous as-deposited film, the silicon nanoparticle forms, after post-thermal annealing at 850° C., in which the grain size is about 3.3 nm. When the temperature is increased to 900° C., crystal size increased to 48 Å. Further increases in temperature, e.g., to about 950° C., do not further increase the crystal size, indicating a depletion of available local silicon atoms.

From these results, it is apparent that by using DC reactive sputtering system, the SiOₓ film, with an x value of between 0 to 2 may be deposited. Rare-earth doping may also be achieved by using another target containing the dopant to perform a co-sputter process, or by using a dopant-embedded target. The size of silicon nanoparticles may be controlled by thermal annealing. This method provides a convenient way to optimize fabrication process.

Thus, a method to make silicon nanoparticle from silicon rich-oxide by DC reactive sputtering for photoluminescence application has been disclosed. It will be appreciated that further variations and modifications thereof may be made within the scope of the invention as defined in the appended claims.

1. A method of forming a silicon-rich silicon oxide layer having nanometer sized silicon particles therein, comprising:
preparing a substrate;
preparing a target;
placing the substrate and the target in a sputtering chamber;
setting the sputtering chamber parameters;
depositing material from the target onto the substrate to form a silicon-rich silicon oxide layer; and
annealing the substrate to form nanometer sized silicon particles therein.

2. The method of claim 1 wherein said preparing a substrate includes preparing a bulk silicon substrate.

3. The method of claim 1 wherein said preparing a target includes preparing a target taken from the group of targets consisting of pure silicon and doped silicon targets.

4. The method of claim 1 wherein said setting the sputtering chamber parameters includes setting the chamber temperature at a temperature from about room temperature to about 250° C., and maintaining the chamber pressure at between about 7 mtorr. to 8 mtorr.

5. The method of claim 1 wherein said setting the sputtering pressure chamber parameters includes providing a gas flow having between about 30% O₂ to 0% O₂, with the remaining gas percentage being argon.

6. The method of claim 1 wherein said annealing includes annealing the substrate at a temperature of between about 850° C. to 1,200° C.

7. A method of forming a silicon-rich silicon oxide layer having nanometer sized silicon particles therein, comprising:
preparing a substrate;
preparing a target;
placing the substrate and the target in a sputtering chamber;
setting the sputtering chamber parameters, including providing a gas flow having between about 30% O₂ to 0% O₂, with the remaining gas percentage being argon;
depositing material from the target onto the substrate to form a silicon-rich silicon oxide layer; and
annealing the substrate to generate nanometer sized silicon particles therein

8. The method of claim 7 wherein said preparing a substrate includes preparing a bulk silicon substrate.

9. The method of claim 7 wherein said preparing a target includes preparing a target taken from the group of targets consisting of pure silicon and doped silicon targets.

10. The method of claim 7 wherein said setting the sputtering chamber parameters includes setting the chamber temperature at a temperature from about room temperature to about 250° C., and maintaining the chamber pressure at between about 7 mtorr. to 8 mtorr.

11. The method of claim 7 wherein said annealing includes annealing the substrate at a temperature of between about 850° C. to 1,200° C.
